(19) United States
(12) Patent Application Publication
(10) Pub. No.: US 2010/0140079 A1
(43) Pub. Date: Jun. 10, 2010

(54) PREPARATION OF A PH SENSOR, THE PREPARED PH SENSOR, SYSTEM COMPRISING THE SAME AND MEASUREMENT USING THE SYSTEM

(75) Inventors: Jung-Chuan CHOU, Yunlin Hsien (TW); Chih-Hsien YEN, Yilan County (TW)

Correspondence Address: QUINTERO LAW OFFICE, PC, 615 Hampton Dr, Suite A202, Venice, CA, 90291, US

(73) Assignee: NATIONAL YUNLIN UNIVERSITY OF SCIENCE AND TECHNOLOGY, Yunlin (TW)

(21) Appl. No.: 12/704,864

(22) Filed: Feb. 12, 2010

Related U.S. Application Data
(62) Division of application No. 11/372,629, filed on Mar. 9, 2006.

(30) Foreign Application Priority Data
Nov. 1, 2005 (TW) TW94138243

(51) Int. Cl. C23C 14/34

(52) U.S. Cl. 204/192.25

(57) ABSTRACT

Preparation of a pH sensor, the prepared pH sensor, system comprising the same, and measurement using the system. The pH sensor is an extended gate field effect transistor (EGFET) structure. The preparation includes the steps of providing an extended gate ion sensitive field effect transistor comprising an extended gate region, forming a titanium nitride film on the extended gate region by RF sputtering deposition to obtain a pH sensor.

### BACKGROUND OF THE INVENTION

1. Field of the Invention

The present invention relates to a pH sensor, and in particular relates to a pH sensor comprising a titanium nitride film and a system comprising the same.

2. Description of the Related Art

The Ion Sensitive Field Effect Transistor (ISFET), first proposed by Piet

Bergveld in 1970, is similar to the conventional MOSFET (Metal-Oxide-Semiconductor Field Effect Transistor) except that a sensitive film is used in place of the metal gate of the MOSFET. The extended gate ion sensitive field effect transistor (EGISFET) developed from ISFET combines the extended gate containing a sensing membrane with the MOSFET by a conducting wire and has the advantages of simple structure, easy package procedure, low cost, and flexibility in the biomedical application. In addition, EGISFET can be prepared with the standard CMOS process and the obtained EGISFET has higher sensitivity in detecting the pH value of a solution. However, the sensing membrane presently in use includes IrO₂ and SnO₂ which are not materials used in the standard CMOS process.

Patents related to the manufacture of ISFET include U.S. Pat. Nos. 4,812,220, 5,061,976, 5,130,265, 5,387,328, and 5,833,824. U.S. Pat. No. 4,812,220 discloses an enzyme sensor for determining concentration of glutamate. The enzyme sensor includes glutamine synthetase immobilized on a substrate and a pH glass electrode or ISFET. U.S. Pat. No. 5,130,265 discloses an ISFET coated with a carbon thin membrane and then with an electrolytic polymerization membrane of 2,6 xylenol for the measurement of concentration of le ion. If the surface of the electrolytic polymerization membrane of 2,6 xylenol is coated with another ion-selective membrane or enzyme-active membrane, various ions and concentration of a biological substrate can be measured. In addition, U.S. Pat. No. 5,130,265 discloses a multifunctional, ion-selective-membrane sensor using a siloxanic prepolymer. U.S. Pat. No. 5,387,328 discloses a bio-sensor using ISFET with platinum electrode for sensing all biological substances which generate H₂O₂ in enzyme reaction. U.S. Pat. No. 5,833,824 discloses a dorsal substrate guarded ISFET sensor for sensing ion activity of a solution. The sensor includes a substrate and an ISFET semiconductor die. A front surface of the substrate is exposed to the solution, a back surface opposite to the front surface and an aperture extending between the front and back surfaces. The ion-sensitive surface is mounted to the back surface such that the gate region is exposed to the solution through the aperture.

Various materials are used to act as the sensing membrane for the ISFET and EGISFET, such as a-Si:H, a-C:H, Al₂O₃, Si₃N₄, WO₃, SnO₂, and the like. These materials can be prepared by sputtering or plasma chemical vapor deposition, however, they still have some drawbacks in practice. A sensing film with low cost and simple process is, however, still required for commercial application.

### BRIEF SUMMARY OF THE INVENTION

A detailed description is given in the following embodiments with reference to the accompanying drawings.

An object of the invention is to provide a pH sensor. The pH sensor is an extended gate field effect transistor (EGFET) structure with a TiN sensing membrane which has low sheet resistance, good conductivity, high melting point (about 2930° C.) with stability at high temperature, good adhesion to metal media, and anticorrosive properties.

The second object of the invention is to provide a low cost process for the preparation of TiN film for ISFET by sputtering deposition. The process is performed under a low temperature and low pressure, and an uniform film with large area can be obtained.

The third object of the invention is to provide a system of measuring pH value in a solution including the pH sensor. A curve for the gate voltage versus source/drain current of the pH sensor in the solution can be measured and the sensitivity of the pH sensor is obtained.

Accordingly, one embodiment of the preparation of a pH sensor, which is an extended gate ion sensitive field effect transistor (EGISFET), includes the steps of providing an extended gate ion sensitive field effect transistor comprising an extended gate region, and forming a titanium nitride film on the extended gate region by radio frequency (RF) sputtering deposition to obtain a pH sensor. The RF sputtering deposition can be performed with a titanium target under conditions of a mixture of Ar and N₂ at a ratio of 1:2 to 1:5 and a flow rate of 60-90 sccm, a pressure of 0.01 to 0.04 torr, and a power of 85 to 120 W.

The embodiment of the pH sensor is an extended gate ion sensitive field effect transistor (EGISFET). The pH sensor includes a metal oxide semiconductor field effect transistor (MOSFET), an extended gate as a sensing unit including a substrate and a titanium nitride film thereon, a conductive wire connecting the MOSFET and the sensing unit, and an insulating layer covering the surface of the sensing unit and exposing the titanium nitride film.

The embodiment of the system of measuring pH value in a solution includes the above-mentioned pH sensor; a reference electrode supplying stable voltage; a semiconductor characteristic instrument connecting the pH sensor and the reference electrode respectively; a temperature controller including a temperature control center, a thermocouple, and a heater; and a light-isolation container isolating the sensing unit from the photosensitive effect. The temperature control center connects the thermocouple and the heater, respectively. Measurement of the pH value of a solution includes the steps of pouring a solution into the light-isolation container; immersing the sensing unit of the pH sensor, the reference electrode, and the thermocouple in the solution; adjusting temperature of the solution by the heater controlled by the temperature control center after detecting temperature variation in the solution by the thermocouple; transmitting measurement data from the pH sensor and the reference electrode to the semiconductor characteristic instrument; and reading out current-voltage (I-V) values of the solution by the semiconductor characteristic instrument to obtain pH value of the solution.

A method of measuring sensitivity of the pH sensor using the above-mentioned system is also provided. The method includes the steps of immersing the sensing unit of the pH sensor in an acidic or basic solution, recording a curve of source/drain current versus gate voltage of the pH sensor by the semiconductor characteristic instrument after altering pH values of the acidic or basic solution at a fixed temperature, and examining the curve to obtain a sensitivity of the pH sensor at the fixed temperature and a fixed current.

### BRIEF DESCRIPTION OF THE DRAWINGS

The present invention can be more fully understood by reading the subsequent detailed description and examples with references made to the accompanying drawings, wherein:

FIG. 1 shows a cross section of a conventional ion sensitive field effect transistor.

FIG. 2 shows a cross section of one embodiment of the pH sensor.

FIG. 3 shows a current-voltage measuring system for the measurement of the sensitivity of the embodiment of the pH sensor.

FIG. 4 shows a source/drain current-gate voltage curve of the embodiment of the pH sensor under various pH values at 25° C.

FIG. 5 shows a gate voltage-pH curve of the embodiment of the pH sensor under various pH values at 25° C.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

Preparation of a pH sensor, the prepared pH sensor, a system comprising the same, and measurement using the system are provided.

The pH sensor is an extended gate field effect transistor (EGFET) structure with a titanium nitride (TiN) film as a sensing membrane. Titanium nitride is a commonly used material for the barrier layer in the CMOS standard process. Detection by an EGFET is described as follows. First, a titanium nitride sensitive film is exposed to an acidic or basic solution, and adsorbent hydrogen ions of the titanium nitride sensitive film are converted to electronic signals. The threshold voltage of a MOSFET is then controlled by the electronic signals. Finally, hydrogen ion concentration is obtained by examining current values.

One embodiment of the preparation of a pH sensor includes the steps of providing an extended gate ion sensitive field effect transistor comprising an extended gate region, forming a titanium nitride film on the extended gate region by radio frequency (RF) sputtering deposition to obtain the pH sensor. The phenomenon of sputtering deposition consists of material erosion from a target on an atomic scale, and the formation of a thin layer of the extracted material on a suitable substrate. The process is initiated in a glow discharge produced in a vacuum chamber under pressure-controlled gas flow. Target erosion occurs due to energetic particle bombardment by either reactive or non-reactive ions produced in the discharge. Specifically, the gas flow is a mixture of argon and nitrogen gas with a ratio of 1:2 to 1:5, preferably 1:4 to 1:5, in a flow rate of 30 to 90 sccm, preferably 60 to 90 sccm, more preferably 60 sccm. The pressure can be 0.01 to 0.04 torr, preferably 0.02 to 0.03 torn The power is 85 to 120 W, preferably 90 to 100 W.

The embodiment of the preparation of the pH sensor provides a low temperature process with a low pressure, and the obtained TiN sensing film can be grown in a large area with evenly distribution. The TiN sensing film has a thickness of 2000 to 5000 Å, preferably 3000 to 4000 Å.

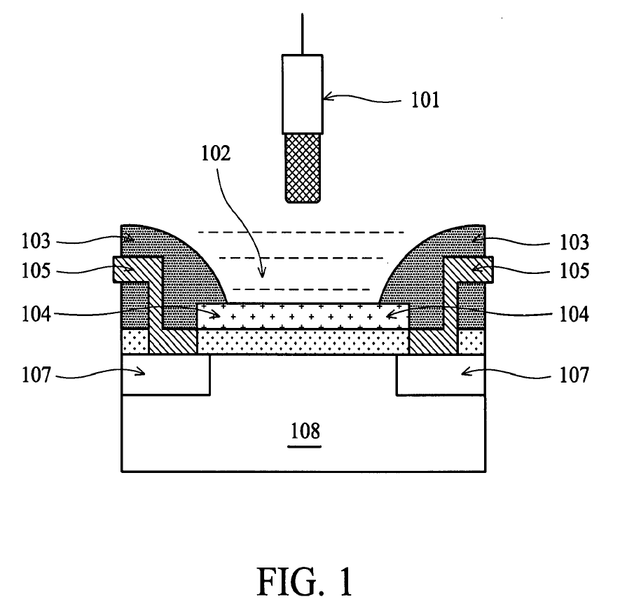

Referring to FIG. 1, a conventional ion sensitive field effect transistor (ISFET) comprises a p-type silicon substrate 108, a gate comprising a silicon dioxide film 106 on the substrate 108, and a sensitive film 104 immobilized on the silicon dioxide film 106, wherein only the sensitive film 104 directly contacts a test solution 102. Other elements of the ISFET are covered by an insulation region 103 comprising epoxy resin. Both sides of the silicon dioxide film 106 in the substrate are n-type heavy doped regions (source/drain) 107. A conductive wire 105, such as aluminum wire, connects the transistor such that source/drain electronic signals can be transmitted to additional circuits thereby after the test solution 102 is detected by the sensitive film 104. In addition, a reference electrode 101 supplying stable voltage avoids noise disturbance.

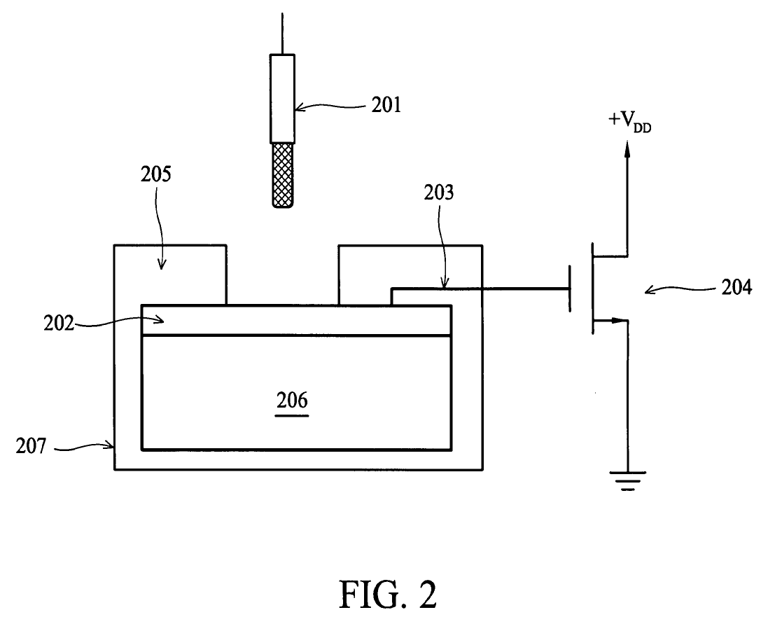

An extended gate field effect transistor (EGFET) is developed from an ISFET. A sensitive film is isolated from a gate of an ISFET, that is, a metal oxide semiconductor field effect transistor (MOSFET) is completely isolated from a test solution to prevent unstable characteristics on semiconductor elements and decrease interference from the test solution. Referring to FIG. 2, an extended gate field effect transistor comprises a sensing unit 207 and a n-type MOSFET 204, wherein the sensing unit 207 comprises a p-type (100) silicon substrate 206 with an electric resistance of 8 to 12 Ω•cm and a size of 0.5×0.5 cm², and a titanium nitride film 202 on the p-type silicon substrate 206. A conductive wire 203 connects the sensing unit 207 and the gate of the MOSFET 204. The sensing unit 207 is covered by an insulation region 205, partially exposing titanium nitride film 202 to contact a test solution. A reference electrode 201 is still required for supplying stable voltage to avoid noise disturbance.

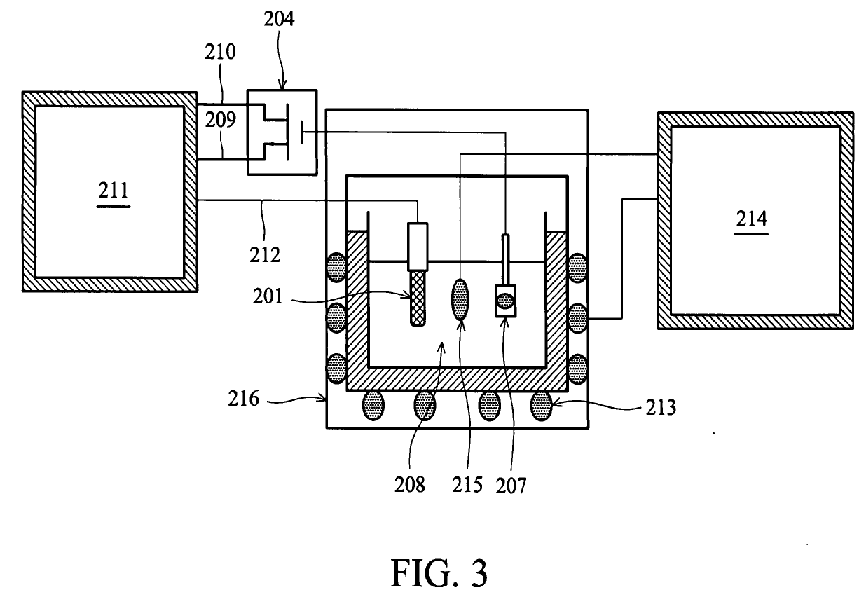

The current-voltage (I-V) system as showed in FIG. 3 measures the sensitivity of the embodiment of the pH sensor with a titanium nitride sensing film. A sensing unit 207 of a pH sensor is immersed in a test solution 208 in a container. A semiconductor characteristic instrument 211, such as Keithley 236, connects a source and a drain of a MOSFET 204 of the pH sensor by conductive wires 209 and 210, such as aluminum wire, to process electronic signals.

In addition, a reference electrode 201 is immersed in the test solution 208 to supply stable voltage. The reference electrode 201 is an Ag/AgCl reference electrode. The reference electrode 201 connects the semiconductor characteristic instrument 211 by a conductive wire 212. A set of heaters 213 is installed outside the container, connecting a temperature controller 214 (temperature control center). When temperatures of the test solution 208 are altered, the temperature controller 214 may drive the heaters 213 to adjust the test solution temperature, wherein a thermocouple 215 of the temperature controller 214 detects the temperature of the test solution 208. The test solution 208, the heaters 213, and other elements contacting the test solution 208 are placed in a light-isolation container 216, such as a dark box, to prevent the photosensitive effect.

The method of measuring pH value of a solution using the above-mentioned system is described in the following. The sensing unit 207, the reference electrode 201, and the thermocouple 215 are immersed in a test solution 208. When the thermocouple 215 detects an altered temperature of the test solution 208, the temperature controller 214 may drive the heaters 213 to adjust the test solution temperature to a fixed temperature, 25° C. The measurement of the sensing unit 207 and the reference electrode 201 can be transmitted to the semiconductor characteristic instrument 211, and the pH value of the test solution 208 can be read therefrom.

The method of measuring the sensitivity of the embodiment of the pH sensor using the above-mentioned system is described in the following. First, sensing unit 207 (titanium nitride sensing film) of the pH sensor is immersed in a test solution 208. Subsequently, pH values of the test solution are altered from 1 to 13 at a fixed temperature, generally 25° C. Next, the semiconductor characteristic instrument supplies a voltage from 0 to 6V to the reference electrode 201 and a fixed voltage of 0.2V to the source/drain of the pH sensor. Next, a curve of source/drain current versus gate voltage of the pH sensor is recorded by the semiconductor characteristic instrument. Finally, the curve is examined to obtain a sensitivity of the pH sensor at the fixed temperature and a fixed current.

Practical examples are described herein.

### EXAMPLE

### Example 1

### Preparation of a TiN sensing film

A p-type (100) silicon substrate with an electric resistance of 8 to 12 Ω•cm and a size of 0.5 cm×0.5 cm was immersed in deionized water and ultrasound washed, and water on the substrate was removed with nitrogen spray. The base pressure of the reaction chamber was maintained at least 10⁻⁶ torr. The mixture of Ar/N₂ (10/50) was introduced into the reaction chamber with a flow rate of 60 sccm and a pressure of 0.02 torr. Deposition power was 100 W. The titanium nitride film was formed on the silicon substrate after 30-min sputtering, and the sensing unit deposited with a titanium nitride film was obtained.

The sensing unit was covered by epoxy resin (EPO-TEK H77 lid sealing epoxy), exposing partial titanium nitride film to form a sensing window. The sensing unit was connected with a gate of a MOSFET by an aluminum wire.

### Example 2

### Measurement of sensitivity of the pH sensor

Sensitivity of the pH sensor was determined with the current-voltage measuring system as shown in FIG. 3. The sensing unit 207 and an Ag/AgCl reference electrode 201 were immersed in a test solution 208. A current-voltage curve of an EGFET in the test solution was measured by a semiconductor characteristic instrument 211 (Keithley 236). The temperature of the test solution was controlled at 25° C. The semiconductor characteristic instrument (Keithley 236) supplied a fixed voltage of 0.2 V to the source/drain of the pH sensor (V_{DS}=0.2 V) and a voltage from 0 to 6 V to the reference electrode. A curve of source/drain current versus gate voltage of the pH sensor was recorded. The threshold voltage (V_{T}) increased with the increasing pH value. Consequently, the variation of the threshold voltage of the pH sensor (i.e. the sensitivity of the pH sensor, S) in aqueous solutions with various pH values was calculated by the formula:

S=ΔV_{T}/ΔpH (mV/pH)

wherein, ΔV_{T} is the variation of threshold voltage of the pH sensor in solutions with various pH values (ΔpH). The sensitivity of the pH sensor at a fixed temperature (25° C.) can be obtained.

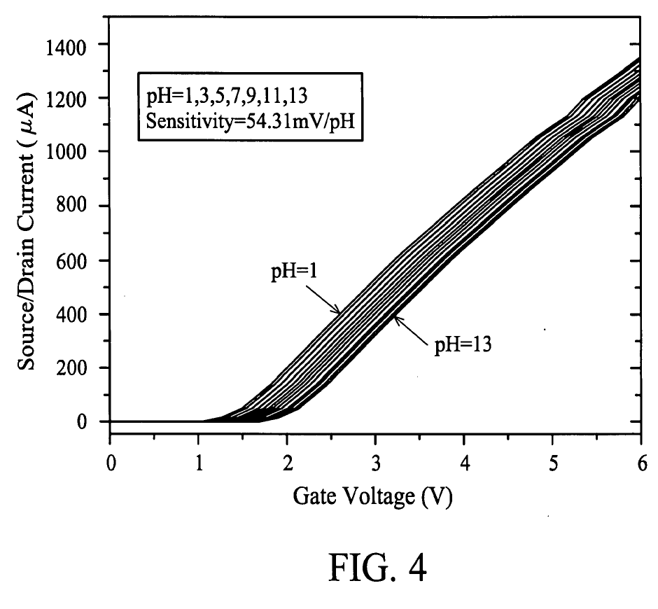

The curves of source/drain current versus gate voltage of the pH sensor in solutions with various pH values at 25° C. are shown in FIG. 4. The results showed that the threshold voltage increased with the increasing pH value.

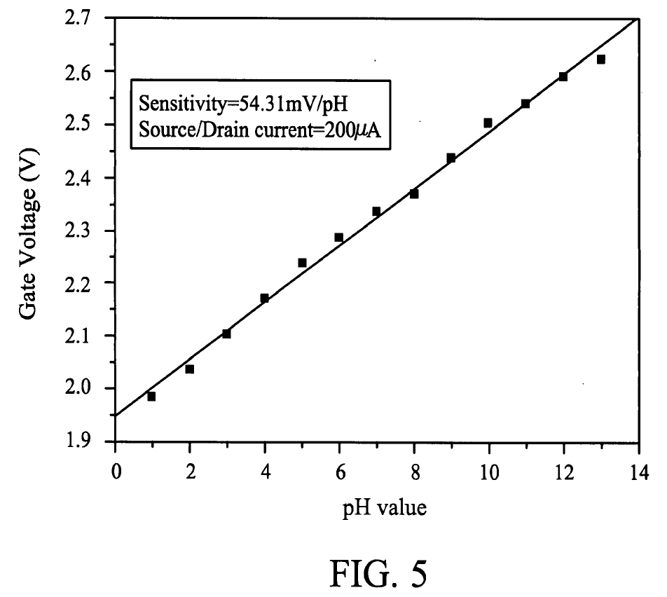

The curve of gate voltage versus pH value of the pH sensor at 25° C. is shown in FIG. 5. The slope of the curve indicates that the pH sensor has a sensitivity of 54.31 mV/pH. This result proved that the titanium nitride sensing film of the invention is suitable for the measurement of pH value in aqueous solutions.

As described above, the advantages of the pH sensor with a titanium nitride sensing film include: The preparation is based on sputtering deposition. This process meets the standard MOS process and is first applied to the extended gate ion-sensitive field effect transistor. The obtained pH sensor has short reaction time and high sensitivity. In addition, the pH sensor is trace detectable and can be applied to monitor and detect the industrial effluents, particularly the acidic effluent. The embodiment of the system of measuring pH value in a solution and the method using the same can be applied not only to the pH sensor of the invention, but also to other extended gate ion-sensitive field effect transistors with various sensing films.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A preparation method of a pH sensor which is an extended gate ion-sensitive field effect transistor structure, the method comprising the steps of:
providing an extended gate ion sensitive field effect transistor comprising an extended gate region; and
forming a titanium nitride film on the extended gate region by radio frequency (RF) sputtering deposition to obtain a pH sensor;
wherein the RF sputtering deposition is performed with a titanium target under conditions of a mixture of Ar and N2 at a ratio of 1:2 to 1:5 and a flow rate of 60-90 sccm, a pressure of 0.01 to 0.04 torr, and a power of 85 to 120 W.

2. The preparation method as claimed in claim 1, wherein the ratio of Ar and N2 is 1:5.

3. The preparation method as claimed in claim 1, wherein the flow rate of the mixture is 60 sccm.

4. The preparation method as claimed in claim 1, wherein the pressure is 0.02 torr.

5. The preparation method as claimed in claim 1, wherein the power is 100 W.

6-23. (canceled)
